(19) United States
(12) Patent Application Publication
(10) Pub. No.: US 2026/0026270 A1
(43) Pub. Date: Jan. 22, 2026

(54) ALKYNES AND ALKENES FOR BLOCKING FILM DEPOSITION ON SILICON

(71) Applicant: Applied Materials, Inc., Santa Clara, CA (US)

(72) Inventors: Lisa J. Enman, Sunnyvale, CA (US); Bhaskar Jyoti Bhuyan, San Jose, CA (US); Aaron Dangerfield, San Jose, CA (US); Sai Hooi Yeong, Cupertino, CA (US); Mark Saly, Santa Clara, CA (US); Lakmal C. Kalutarage, San Jose, CA (US); Seyed Mahmoud Hosseini, Sunnyvale, CA (US)

(73) Assignee: Applied Materials, Inc., Santa Clara, CA (US)

(21) Appl. No.: 18/775,104

(22) Filed: Jul. 17, 2024

(51) Int. Cl. H01L 21/02

(52) U.S. Cl. CPC H01L 21/02312; H01L 21/02301; H01L 21/02126; H01L 21/02145; H01L 21/02164; H01L 21/0217; H01L 21/02178

(57) ABSTRACT

Methods of selectively depositing a low-k dielectric film are described. In one or more embodiments, the methods include exposing a substrate to a blocking compound, the substrate including a first surface and a second surface, the first surface including hydrogen-terminated silicon, the blocking compound selectively depositing on the first surface to form a blocked first surface; and selectively depositing the low-k dielectric film on the second surface. Methods of forming an inner spacer layer are described. In one or more embodiments, the methods include pretreating a substrate to remove oxide from a hydrogen-terminated silicon (Si) channel of the substrate, the substrate including the hydrogen-terminated silicon channel and a silicon germanium (SiGe) surface; exposing the substrate to a blocking compound, the blocking compound selectively depositing on the hydrogen-terminated silicon (Si) channel to form a blocked silicon channel; and depositing the inner spacer layer selectively on the silicon germanium surface.

### TECHNICAL FIELD

Embodiments of the present disclosure generally relate to electronic devices and methods of forming electronic devices. In particular, embodiments of the present disclosure relate to methods of blocking or hindering film deposition on silicon surfaces, including using alkynes or alkenes.

### BACKGROUND

The transistor is a key component of most integrated circuits. Since the drive current, and therefore speed, of a transistor is proportional to the gate width of the transistor, faster transistors generally require larger gate width. Thus, there is a trade-off between transistor size and speed, and “fin” field-effect transistors (FinFETs) have been developed to address the conflicting goals of a transistor having maximum drive current and minimum size. FinFETs are characterized by a fin-shaped channel region that greatly increases the size of the transistor without significantly increasing the footprint of the transistor and are now being applied in many integrated circuits. FinFETS, however, have their own drawbacks.

As the feature sizes of transistor devices continue to shrink to achieve greater circuit density and higher performance, there is a need to improve transistor device structure to improve electrostatic coupling and reduce negative effects such as parasitic capacitance and off-state leakage. Examples of transistor device structures include a planar structure, a fin field effect transistor (FinFET) structure, and a gate all around (GAA) structure. The GAA device structure includes several lattice matched channels suspended in a stacked configuration and connected by source/drain regions. The GAA structure provides good electrostatic control and may find broad adoption in complementary metal oxide semiconductor (CMOS) wafer manufacturing.

The formation of the channel region of GAA includes forming a series of nanosheets across the channel, where the nanosheets may be arranged in a parallel orientation and each nanosheet is separated from each neighboring nanosheet by a space or “void”. The formation of the nanosheets may involve an epitaxy loop to deposit alternating layers of semiconductor material, such as silicon (Si), and release layers, such as silicon germanium (SiGe), to form the channel.

In conventional methods of forming GAA transistors, the inner spacer dielectric layer is deposited before the epitaxial growth of the source/drain material in the source/drain regions. The growth of the source/drain material, however, at interfaces with the inner spacer layer can induce stacking faults. These faults can lead to a lack of compressive strain in the PMOS channel leading to lower overall GAA PMOS activity.

Thus, there remains an ongoing need in the art for methods that can deposit inner spacer layers in the GAA nanosheets while minimizing defects in the resulting transistor.

### SUMMARY

One or more embodiments of the disclosure are directed methods of selectively depositing a low-k dielectric film. In one or more embodiments, the method includes: exposing a substrate to a blocking compound, the substrate including a first surface and a second surface, the first surface including hydrogen-terminated silicon and the second surface including silicon germanium (SiGe), the blocking compound including at least one carbon-carbon double bond or carbon-carbon triple bond, the blocking compound selectively depositing on the first surface over the second surface to form a blocked first surface; and selectively depositing the low-k dielectric film on the second surface over the blocked first surface. Additional embodiments of the disclosure are directed to methods of forming an inner spacer layer in a GAA transistor. In one or more embodiments, the method includes: pretreating a substrate to remove oxide from a hydrogen-terminated silicon (Si) channel of the substrate, the substrate including the hydrogen-terminated silicon channel and a silicon germanium (SiGe) surface; exposing the substrate to an oxidizing environment; exposing the substrate to a blocking compound, the blocking compound including at least one carbon-carbon double bond or carbon-carbon triple bond, the blocking compound selectively depositing on the hydrogen-terminated silicon (Si) channel over the silicon germanium (SiGe) surface to form a blocked silicon channel; and depositing the inner spacer layer selectively on the silicon germanium surface over the blocked silicon channel.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a process flow diagram of a method according to one or more embodiments;

FIG. 2 illustrates a cross-sectional view of a substrate during semiconductor processing according to one or more embodiments;

FIG. 3 illustrates a process flow diagram of a method according to one or more embodiments;

FIG. 4A illustrates a cross-sectional view of a substrate during semiconductor processing according to one or more embodiments;

FIG. 4B illustrates a cross-sectional view of a substrate during semiconductor processing according to one or more embodiments; and

FIG. 4C illustrates a cross-sectional view of a substrate during semiconductor processing according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of +15%, or less, of the numerical value. For example, a value differing by +14%, +10%, +5%, +2%, or +1%, would satisfy the definition of about.

As used in this specification and the appended claims, the term “substrate” or “wafer” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” or “substrate surface”, as used herein, refers to any portion of a substrate or portion of a material surface formed on a substrate upon which film processing is performed. For example, a substrate surface on which processing can be performed includes materials such as silicon, silicon oxide, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate. Substrates may have various dimensions, such as 200 mm or 300 mm diameter wafers, as well as rectangular or square panes. In one or more embodiments, the substrate comprises a rigid discrete material.

As used herein, the terms “reactive compound”, “reactive gas”, “reactive species”, “precursor”, “process gas” and the like are used interchangeably to mean a substance with a species capable of reacting with the substrate or material on the substrate in a surface reaction (e.g., chemisorption, oxidation, reduction, cycloaddition). The substrate, or portion of the substrate, is exposed sequentially to the two or more reactive compounds which are introduced into a reaction zone of a processing chamber.

As used herein, the term “purge” or “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In one or more embodiments, purging the processing region comprises flowing a purge gas over the substrate. In one or more embodiments, the purge process comprises flowing an inert gas. In one or more embodiments, the purge gas is selected from one or more of nitrogen (N₂), helium (He), and argon (Ar). In one or more embodiments, a reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

As used in this specification and the appended claims, the term “selectively” refers to a process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

As used herein, the phrase “selectively over,” or similar phrases, means that the subject material is deposited on the stated surface to a greater extent than on another surface. In one or more embodiments, “selectively” means that the subject material forms on the selective surface at a rate greater than or equal to about 10×, 15×, 20×, 25×, 30×, 35×, 40×, 45× or 50× the rate of formation on the non-selected surface. In one or more embodiments, the passivation layer forms on the selective and does not form on the non-selective surface with a selectivity ratio of at least about 10:1, or at least about 100:1, or at least about 1000:1.

The term “on” indicates that there is direct contact between elements. The term “directly on” indicates that there is direct contact between elements with no intervening elements.

As used herein, the term “alkyl” or “alk,” alone or as part of another group, includes both straight and branched chain hydrocarbons, containing 1 to 24 carbons, or 1 to 14 carbon atoms, or 1 to 12 carbon atoms, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents. The alkyl may be substituted or unsubstituted.

The alkyl groups, including cyclic alkyl groups, may optionally include up to 1 to 4 substituents such as halo, for example F, Br, Cl, or I, or CF₃, alkyl, alkoxy, aryl, aryloxy, aryl(aryl) or diaryl, arylalkyl, arylalkyloxy, alkenyl, cycloalkyl, cycloalkylalkyl, cycloalkylalkyloxy, amino, hydroxy, hydroxyalkyl, acyl, heteroaryl, heteroaryloxy, heteroarylalkyl, heteroarylalkoxy, aryloxyalkyl, alkylthio, arylalkylthio, aryloxyaryl, alkylamido, alkanoylamino, arylcarbonylamino, nitro, cyano, thiol, haloalkyl, trihaloalkyl, and/or alkylthio, and the like.

As used herein, the term “alkene” or “alkenyl” refers to straight or branched chain radicals of 2 to 24 carbons, or 2 to 12 carbons, or 2 to 8 carbons in the normal chain, which include at least one double bond in the normal chain, such as vinyl, 2-propenyl, 3-butenyl, 2-butenyl, 4-pentenyl, 3-pentenyl, 2-hexenyl, 3-hexenyl, 2-heptenyl, 3-heptenyl, 4-heptenyl, 3-octenyl, 3-nonenyl, 4-decenyl, 3-undecenyl, 4-dodecenyl, 4,8,12-tetradecatrienyl, and the like, and which may be optionally substituted with 1 to 4 substituents, namely, halogen, haloalkyl, alkyl, alkoxy, alkenyl, alkynyl, aryl, arylalkyl, cycloalkyl, amino, hydroxy, heteroaryl, cycloheteroalkyl, alkanoylamino, alkylamido, arylcarbonyl-amino, nitro, cyano, thiol, alkylthio, and/or any of the alkyl substituents set out herein.

As used herein, the term “alkyne” or “alkynyl” refers to straight or branched chain radicals of 2 to 24 carbons, or 2 to 12 carbons, or 2 to 8 carbons in the normal chain, which include at least one triple bond in the normal chain, such as 2-propynyl, 3-butynyl, 2-butynyl, 4-pentynyl, 3-pentynyl, 2-hexynyl, 3-hexynyl, 2-heptynyl, 3-heptynyl, 4-heptynyl, 3-octynyl, 3-nonynyl, 4-decynyl, 3-undecynyl, 4-dodecynyl, and the like, and which may be optionally substituted with 1 to 4 substituents, namely, halogen, haloalkyl, alkyl, alkoxy, alkenyl, alkynyl, aryl, arylalkyl, cycloalkyl, amino, heteroaryl, cycloheteroalkyl, hydroxy, alkanoylamino, alkylamido, arylcarbonylamino, nitro, cyano, thiol, and/or alkylthio, and/or any of the alkyl substituents set out herein.

As used herein, the term “aryl” refers to monocyclic and bicyclic aromatic groups containing 4 to 10 carbons in the ring portion (such as phenyl, biphenyl or naphthyl, including 1-naphthyl and 2-naphthyl) and may optionally include 1 to 3 additional rings fused to a carbocyclic ring or a heterocyclic ring (such as aryl, cycloalkyl, heteroaryl, or cycloheteroalkyl rings). The aryl group may be optionally substituted through available carbon atoms with 1, 2, or 3 substituents, for example, hydrogen, halo, haloalkyl, alkyl, haloalkyl, alkoxy, haloalkoxy, alkenyl, trifluoromethyl, trifluoromethoxy, alkynyl, and the like.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source(S), through which the carriers enter the channel; drain (D), through which the carriers leave the channel; and gate (G), the terminal that modulates the channel conductivity. Conventionally, current entering the channel at the source(S) is designated Is and current entering the channel at the drain (D) is designated Ip. Drain-to-source voltage is designated VDs. By applying voltage to gate (G), the current entering the channel at the drain (i.e., ID) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “gate all-around (GAA),” is used to refer to an electronic device, e.g. a transistor, in which the gate material surrounds the channel region on all sides. The channel region of a GAA transistor may include nanowires or nanoslabs, bar-shaped channels, or other suitable channel configurations known to one of skill in the art (collectively termed “nanosheets” herein). In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

A “dielectric material,” as used herein, refers to an electrical insulator material that can be polarized by an applied electric field. Non-limiting examples of dielectric material include silicon oxide (SiOₓ), silicon nitride (SiₓN_{y}), silicon (Si), silicon oxynitride (SiON), carbides, oxycarbides, nitrides, oxynitrides, oxycarbonitrides, polymers, phosphosilicate glass, fluorosilicate (SiOF) glass, organosilicate glass (SiOCH), aluminum oxide (AlOₓ), hafnium oxide (HfOₓ), zirconium oxide (ZrO₂), titanium oxide (TiOₓ), titanium nitride (TiN), tantalum oxide (TaₓO₅), yttrium oxide (Y₂O₃), lanthanum oxide (La₂O₃), aluminum nitride (AlN), magnesium oxide (MgO), calcium fluoride (CaF₂), lithium fluoride (LiF), strontium oxide (SrO), barium oxide (BaO), hafnium silicate (HfSiO₄), lanthanum aluminate (LaAlO₃), niobium pentoxide (Nb₂O₅), barium titanate (BaTiO₃), strontium titanate (SrTiO₃), bismuth titanate (Bi₄Ti₃O₁₂), lead zirconium titanate (Pb(Zr, Ti)O₃), calcium copper titanate (CaCu₃Ti₄O₁₂), lithium niobate (LiNbO₃), barium titanate (BaTiO₃), and potassium niobate (KNbO₃). In one or more embodiments, the dielectric material is silicon germanium (SiGe).

A “low-k dielectric material” or “low-k dielectric film”, as used herein, has a k value of less than about 8, or less than about 7, or less than about 5.

One or more embodiments of the present disclosure are directed to methods of selectively depositing a low-k dielectric film.

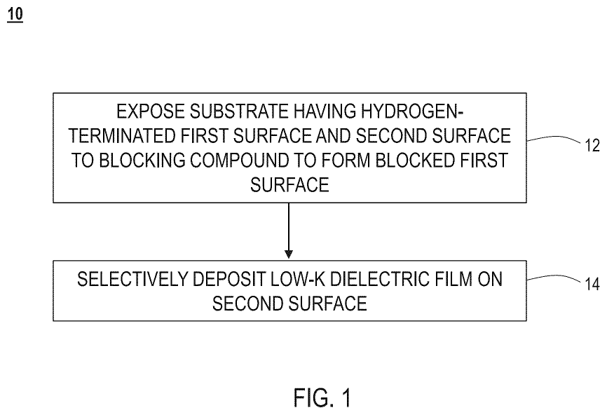

In one or more embodiments, a method 10 of the present disclosure includes operations as illustrated in the process flow diagram of FIG. 1. Referring to FIG. 1, at operation 12, in one or more embodiments, a substrate having a hydrogen-terminated first surface and a second surface is exposed to a blocking compound to form a first blocked surface. As used herein, the term “blocking compound” refers any chemical compound capable of selectively preventing or hindering deposition on a surface. In some embodiments, the blocking compound may form a blocking layer of chemical compounds, while in other embodiments, the blocking compounds merely spatially prevent deposition on the substrate surface.

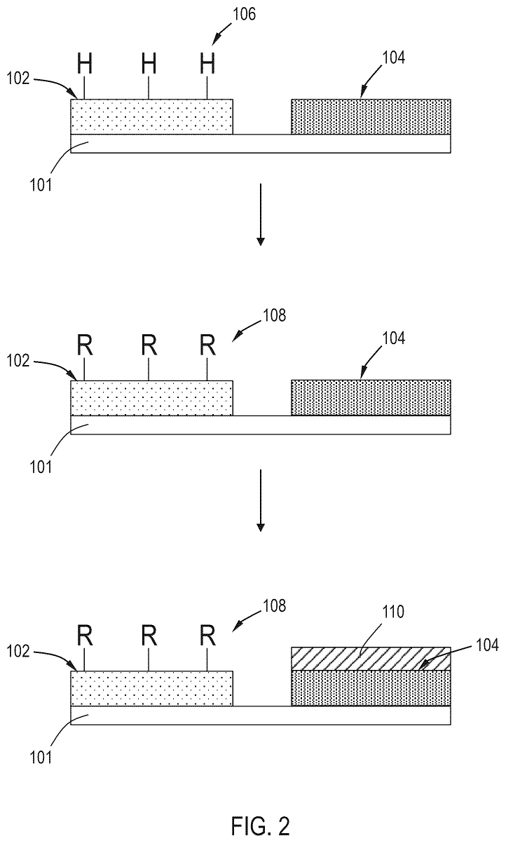

In one or more embodiments, the substrate may have a structure as illustrated schematically in FIG. 2. In one or more embodiments, the substrate 101 may have a hydrogen-terminated first surface 102 including terminal hydrogens 106. The substrate 101 may also have a second surface 104. In one or more embodiments, the hydrogen-terminated first surface 102 may comprise hydrogen-terminated silicon (H—Si). In one or more embodiments, the hydrogen-terminated first surface 102 may consist essentially of hydrogen-terminated silicon. As used herein, the term “consists essentially of” means that at least 80%, or at least 90%, or at least 95%, or at least 98%, or at least 99%, of the first surface is hydrogen-terminated silicon. In one or more embodiments, the first surface is 100% hydrogen-terminated silicon.

In one or more embodiments, the second surface 104 comprises silicon germanium (SiGe). As used herein, terms such as “silicon germanium” refer to materials comprising silicon and germanium. “Silicon germanium” should not be understood to imply any stoichiometric ratio, unless indicated otherwise. Stated differently, a material comprising silicon germanium may be stoichiometric or non-stoichiometric, silicon-rich, or silicon-poor. In one or more embodiments, the silicon germanium (SiGe) of the second surface 104 may have a germanium concentration in a range of from 5 atomic % to 50 atomic %, or from 5 atomic % to 15 atomic %.

In one or more embodiments, the blocking compound can be delivered to the substrate as a single compound or sequential exposure of multiple compounds to form a blocking layer. In some embodiments, the surface is exposed to a single compound that assembles on the surface in an ordered or semi-ordered manner. The blocking compound of one or more embodiments may comprise at least one carbon-carbon double bond, or at least one carbon-carbon triple bond. In one or more embodiments, the blocking compound may comprise an alkyne having a general formula (I):

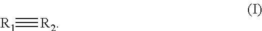

In one or more embodiments, R₁ and R₂ are each independently selected from the group consisting of hydrogen, substituted or unsubstituted C₁₋₂₀ linear alkyl, substituted or unsubstituted C₁₋₂₀ branched alkyl, and substituted or unsubstituted C₁₋₂₀ cyclic alkyl, and substituted or unsubstituted C₄₋₁₀ aryl. In one or more embodiments, one or more of R₁ and R₂ comprises hydrogen, thus forming a terminal alkyne.

In one or more embodiments, the blocking compound comprises cyclooctyne. In one or more embodiments, R₁ and R₂ are the same, forming a symmetric blocking compound, and comprise hydrogen (in other words, acetylene) or a linear C₁₋₂₀ alkyl.

In one or more embodiments, the blocking compound of formula (I) reacts with the hydrogen-terminated surface 102 to form a blocked first surface 108, for example as illustrated schematically in FIG. 2. In FIG. 2, the blocking compound on the blocked first surface 108 is represented as “—R”. The blocking compound may react with the hydrogen-terminated first surface 102 through a triple bond to form a C—Si bond. In one or more embodiments, the blocking compound reacts with the hydrogen-terminated first surface 102 through a hydrosilylation reaction.

In one or more embodiments, the blocking compound may comprise an alkene having a general formula (II):

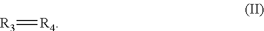

In one or more embodiments, R₃ and R₄ are each independently selected from the group consisting of hydrogen, substituted or unsubstituted C₁₋₂₀ linear alkyl, substituted or unsubstituted C₁₋₂₀ branched alkyl, and substituted or unsubstituted C₁₋₂₀ cyclic alkyl, and substituted or unsubstituted C₄₋₁₀ aryl. In one or more embodiments, one or more of R₃ and R₄ comprises hydrogen, thus forming a terminal alkene.

In one or more embodiments, the blocking compound comprises cyclopentadiene or cyclohexene. In one or more embodiments, R₃ and R₄ are the same, forming a symmetric blocking compound, and comprise hydrogen (in other words, ethylene) or a linear C₁₋₂₀ alkyl.

In one or more embodiments, the blocking compound of formula (II) reacts with the hydrogen-terminated first surface 102 to form a blocked surface 108. The blocking compound may react through a double bond to form a C—Si bond with the hydrogen-terminated first surface 102. In one or more embodiments, the blocking compound of formula (II) reacts with the hydrogen-terminated first surface 102 through a hydrosilylation reaction.

In one or more embodiments, at operation 12 of method 10, the blocking compound, such as the blocking compound of general formula (I) or general formula (II), selectively deposits on the hydrogen-terminated first surface 102 over the second surface 104 to form the blocked first surface 108. A ratio of a deposition rate of the blocking compound on the hydrogen-terminated first surface 102 to the second surface 104 may be about 10:1 or greater, 100:1 or greater, or 1000:1 or greater. In one or more embodiments, substantially no blocking compound is deposited on the second surface 104.

In one or more embodiments, the blocking compound may be deposited by any suitable technique known to the skilled artisan. For example, the blocking compound may be deposited using a suitable chemical vapor deposition (CVD) or plasma enhanced chemical vapor deposition (PECVD) process based on a hydrocarbon gas or mixture of hydrocarbon gases including alkynes, such as alkynes of general formula (I), or alkenes, such as alkenes of general formula (II), or the like, and may also include hydrogen (H₂).

Chemical vapor deposition (CVD) is one of the most common deposition processes employed for depositing layers on a substrate. CVD is a flux-dependent deposition technique that uses precise control of the substrate temperature and the precursors introduced into the processing chamber in order to produce a desired layer of uniform thickness. The reaction parameters become more critical as substrate size increases, creating a need for more complexity in chamber design and gas flow technique to maintain adequate uniformity.

The blocking compound may also be deposited by a suitable atomic layer deposition (ALD) or plasma enhanced atomic layer deposition (PEALD) process based on, for example, a hydrocarbon gas or mixture of hydrocarbon gases. The skilled artisan will be familiar with deposition methods of hydrocarbon layers on semiconductor substrates.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness. In one or more embodiments, there may be two reactants, A and B, which are alternatingly pulsed and purged. In other embodiments, there may be three or more reactants, A, B, and C, which are alternatingly pulsed and purged.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

The substrate may be exposed to the blocking period for a period of time to nearly, or completely, form a layer on the hydrogen-terminated first surface 102. The blocking compound may be delivered in alternating pulses. In one or more embodiments, the pulse times of the blocking compound may be greater than or equal to 0.1 seconds, greater than or equal to 1 second, greater than or equal to 2 seconds, greater than or equal to 3 seconds, greater than or equal to 4 seconds, greater than or equal to 5 seconds, greater than or equal to 10 seconds, greater than or equal to 20 seconds, greater than or equal to 40 seconds, greater than or equal to 60 seconds, greater than or equal to 80 seconds, greater than or equal to 100 seconds, or more. In one or more embodiments, the substrate is exposed to the blocking compound for a time period of greater than or equal to about 1000 seconds.

The substrate, in one or more embodiments, may be exposed to the blocking compound at a processing chamber temperature in a range of from about 100° C. to about 400° C., or in a range of from about 200° C. to about 400° C. In one or more embodiments, the substrate is exposed to the blocking period for a time period of greater than or equal to about 200 seconds at a temperature in a range of from about 100° C. to about 550° C.

In one or more embodiments, prior to exposing the substrate to the blocking compound, the substrate is exposed to a pretreatment to remove oxide from the hydrogen-terminated first surface 102. In one or more embodiments, the pretreatment comprises etching. The hydrogen-terminated first surface 102 may be etched by any suitable etch process known to the skilled artisan that is compatible with a silicon material. In one or more embodiments, the etching uses a wet etch process, such as aqueous alkaline media, non-limiting examples including potassium hydroxide (KOH), sodium hydroxide (NaOH), or tetramethylammonium hydroxide (TMAH) solutions. In one or more embodiments, a dry etch process is used. In some embodiments, the dry etch process may include a conventional plasma etch, or a remote plasma-assisted dry etch process, In the etch process of one or more embodiments, the device is exposed to H₂, NF₃, and/or NH₃ plasma species, e.g., plasma-excited hydrogen and fluorine species. For example, in some embodiments, the device may undergo simultaneous exposure to H₂, NF₃, and NHs plasma. The etch process of one or more embodiments may be performed in any suitable chamber, which may be integrated into one of a variety of multi-processing platforms. In one or more embodiments, a wet etch process may be used which includes a hydrofluoric (HF) acid last process, in which HF etching of surface is performed that leaves surface hydrogen-terminated. Alternatively, any other liquid-based etch process may be employed. In some embodiments, the process comprises a sublimation etch. The etch process can be plasma or thermally based. The plasma processes can be any suitable plasma (e.g., conductively coupled plasma, inductively coupled plasma, microwave plasma. For example, in one or more embodiments, the hydrogen-terminated first surface 102 may be exposed to H₂, NF₃, and/or NHs plasma species, e.g., plasma-excited hydrogen and fluorine species. The etch process may be plasma or thermally based. The plasma etch process can use any suitable plasma (for example, conductively coupled plasma, inductively coupled plasma, or microwave plasma) known to the skilled artisan.

In one or more embodiments, the etching may control surface termination of hydrogen-terminated first surface 102. For example, the etching may form terminal hydrogen groups (—H groups) or remove or reduce the amount of oxide that was present on the hydrogen-terminated first surface 102 prior to the etching.

Referring to FIG. 2, exposing the substrate to the blocking compound, in one or more embodiments, may form a blocked first surface 108. At operation 14 of method 10, in one or more embodiments, a low-k dielectric film 110 is selectively deposited on the second surface 104 over the blocked first surface 108. In one or more embodiments, the low-k dielectric film 110 comprises an insulating material. In one or more embodiments, the low-k dielectric film 110 comprises one or more of silicon oxycarbide (SiOC), silicon oxide (SiO), silicon nitride (SiN), silicon oxycarbonitride (SiOCN), aluminum oxide (AlO), aluminum silicon oxide (AlSiO), and metal oxides having a dielectric constant k with k less than 8. In one or more embodiments, the silicon oxide comprises silicon dioxide (SiO₂).

In one or more embodiments, a thickness of the low-k dielectric film 110 can be about 20 nm or less, or about 15 nm or less, or about 10 nm or less, or about 5 nm or less.

In one or more embodiments, a ratio of a deposition rate of the low-k dielectric film 110 on the second surface 104 to a deposition rate of the low-k dielectric film 110 on the blocked first surface 108 may be about 6:1 or great, or about 10:1 or greater, or about 50:1 or greater, or about 100:1 or greater, or about 1000:1 or greater. In one or more embodiments, substantially no low-k dielectric film 110 is deposited on the blocked first surface 108.

According to one or more embodiments, the low-k dielectric film forms an inner spacer layer of a GAA transistor, and the second surface is a channel material of the GAA transistor.

One or more embodiments of the present disclosure are directed to methods of forming an inner spacer layer in a GAA transistor. One or more embodiments provide for forming the inner spacer layer after deposition of the source/drain material in the source/drain regions. Depositing the inner spacer layer after the source/drain material is deposited requires the use of deposition methods that can deposit films selectively on the GAA liner material over the channel nanosheet material, such as selectively on silicon germanium (SiGe) over silicon (Si).

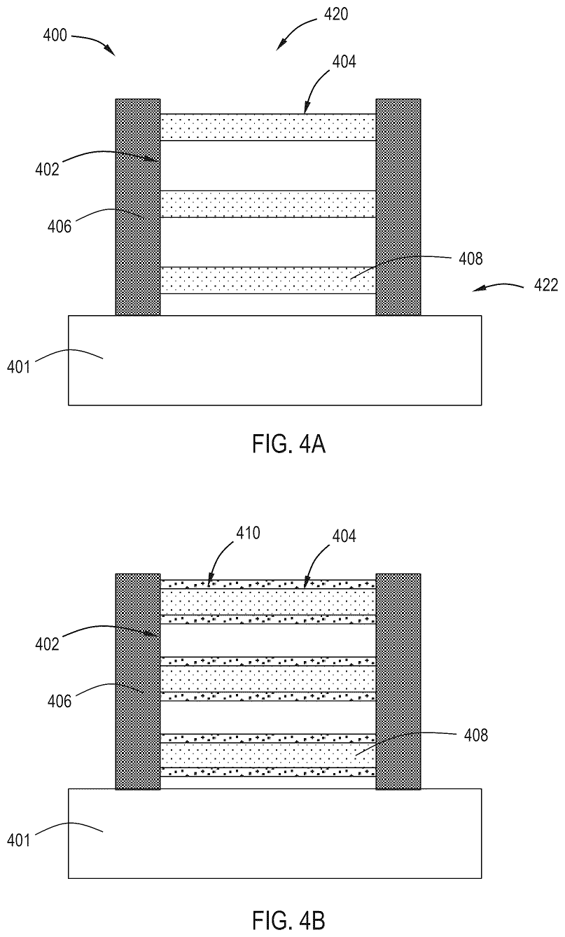

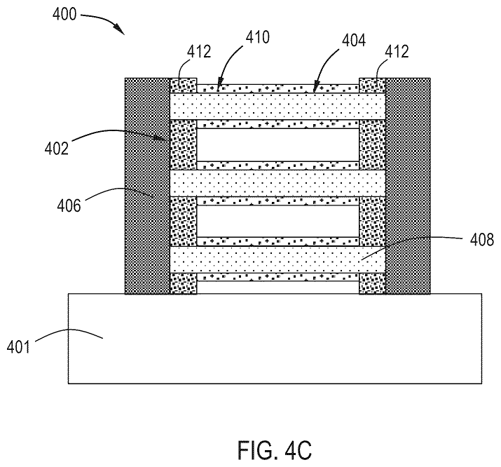

FIG. 4A schematically illustrates a semiconductor device 400 on a substrate 401, the semiconductor device 400 having a channel region 420 and a source/drain region 422. The substrate 401 may comprise a silicon germanium (SiGe) liner 406 having a silicon germanium (SiGe) surface 402. The silicon germanium (SiGe) liner 406 of some embodiments may line a source/drain material filled in the source/drain region 422 (not shown). In one or more embodiments, a silicon (Si) channel 408 having a hydrogen-terminated silicon (Si) surface 404 is present in the channel region 420.

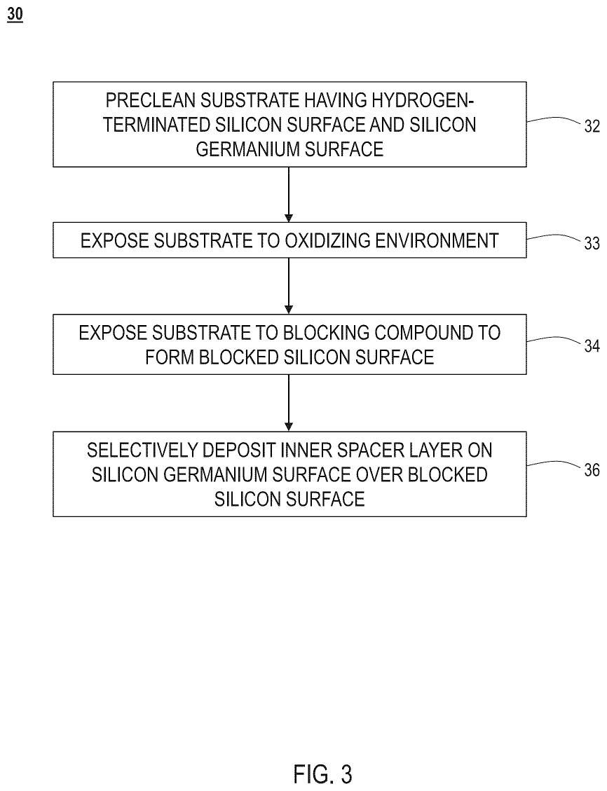

In one or more embodiments, a method 30 of forming an inner spacer layer may have a process flow as shown in FIG. 3. At operation 32 of method 30, in one or more embodiments, the substrate may be exposed to a pretreatment to remove oxide from the hydrogen-terminated silicon (Si) surface 404. The pretreatment may be any suitable pretreatment that can remove oxide from a silicon surface, such as any of the etchings described herein. Suitable pretreatments to remove oxide from silicon layers will be known to the skilled artisan.

At operation 33 of method 30, in one or more embodiments, the substrate is exposed to an oxidizing environment. In one or more embodiments, the oxidizing environment oxidizes the silicon germanium (SiGe) surface 402 at a faster rate than it oxidizes the hydrogen-terminated silicon (Si) surface 404. In one or more embodiments, after operation 33, the silicon germanium (SiGe) surface 402 is an oxidized silicon germanium surface. The oxidizing environment according to one or more embodiments may comprise air, oxygen (O₂), or any other oxidant known to the skilled artisan. The exposing of the substrate to the oxidizing environment may be performed at any suitable pressure, such as at ambient pressure or under vacuum.

At operation 34 of method 30, in one or more embodiments, the substrate is exposed to a blocking compound to form a blocked silicon (Si) surface 410, as illustrated schematically in FIG. 4B. The blocking compound may be a blocking compound of general formula (I) or general formula (II), and may be deposited selectively on the hydrogen-terminated silicon (Si) surface 404 over the silicon germanium (SiGe) surface 402. The blocking compound may be deposited using any deposition method suitable for depositing hydrocarbons, including alkynes and alkenes, such as the CVD and ALD methods described herein. In one or more embodiments, the blocking compound forms a monolayer, or a sub-monolayer, on the hydrogen-terminated silicon (Si) surface 404.

At operation 36 of method 30, in one or more embodiments, an inner spacer layer 412 is deposited selectively on the silicon germanium (SiGe) surface 402 over the blocked silicon (Si) surface 410. In one or more embodiments, the inner spacer layer 412 is a low-k dielectric film, and may comprise one or more of silicon oxycarbide (SiOₓC_{y}), silicon oxide (SiO₂), silicon nitride (SiNₓ), silicon oxycarbonitride (SiOₓC_{y}Nₓ), aluminum oxide (AlOₓ), aluminum silicon oxide (AlSiOₓ), and metal oxides having a dielectric constant k with k<8. A thickness of inner spacer layer 412 may be about 10 nm or less.

In one or more embodiments of the methods provided herein, the methods may comprise removing one or more precursor effluent from the substrate. The removing one or more precursor effluent may comprise purging of the processing chamber. As used in this manner, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of one or more reactive species by any suitable technique including, but not limited to, moving the substrate through a gas curtain to a portion or sector of the processing chamber that contains none or substantially none of the one or more reactive species. In one or more embodiments, purging the processing chamber comprises applying a vacuum. In one or more embodiments, purging the processing chamber comprises flowing a purge gas over the substrate. In one or more embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), neon (Ne), and argon (Ar).

In one or more embodiments, the processing region is in a modular system comprising multiple chambers which perform various functions including substrate center-finding and orientation, degassing, annealing, deposition and/or etching. According to one or more embodiments, the modular system includes at least a first processing chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation, and other substrate processes. By carrying out processes in the processing chamber of a modular system, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In one or more embodiments, the inert gas is used to purge or remove some or all of the reactants (e.g., reactant). According to one or more embodiments, the inert gas is injected at the exit of the processing chamber to prevent reactants (e.g., reactant) from moving from the processing chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In one or more embodiments, the substrate support includes a heater/cooler which can be controlled to change the substrate temperature conductively. In one or more embodiments, the gases (either reactive gases or inert gases) being employed are heated or cooled to locally change the substrate temperature. In one or more embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

In a spatial ALD process, the reactive gases are flowed into different processing regions within a processing chamber. The different processing regions are separated from adjacent processing regions so that the reactive gases do not mix. The substrate can be moved between the processing regions to separately expose the substrate to the reactive gases. During substrate movement, different portions of the substrate surface, or material on the substrate surface, are exposed to the two or more reactive gases so that any given point on the substrate is substantially not exposed to more than one reactive gas simultaneously. As will be understood by those skilled in the art, there is a possibility that a small portion of the substrate may be exposed to multiple reactive gases simultaneously due to diffusion of the gases within the processing chamber, and that the simultaneous exposure is unintended, unless otherwise specified.

A “pulse” or “dose” as used herein refers to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds.

The durations for each pulse/dose are variable and may be adjusted to accommodate, for example, the volume capacity of the processing chamber as well as the capabilities of a vacuum system coupled thereto. Additionally, the dose time of a reactive gas may vary according to the flow rate of the reactive gas, the temperature of the process gas, the type of control valve, the type of process chamber employed, as well as the ability of the components of the process gas to adsorb onto the substrate. Dose times may also vary based upon the type of layer being formed and the geometry of the device being formed. A dose time should be long enough to provide a volume of compound sufficient to adsorb/chemisorb onto substantially the entire surface of the substrate and form a layer of a process gas component thereon.

The disclosure provides that the processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor or controller, transforms the general-purpose computer into a specific purpose computer (controller) that controls the chamber operation such that the processes are performed. The process can be stored on non-transitory computer readable medium including instructions, that, when executed by a controller of a substrate processing chamber, causes the substrate processing chamber to perform the operations of: expose a substrate comprising a hydrogen-terminated first surface and a second surface to a blocking compound to form a blocked first surface, and selectively deposit a low-k dielectric film on the second surface over the blocked first surface.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of selectively depositing a low-k dielectric film, the method comprising:
exposing a substrate to a blocking compound, the substrate comprising a first surface and a second surface, the first surface comprising hydrogen-terminated silicon and the second surface comprising silicon germanium (SiGe), the blocking compound comprising at least one carbon-carbon double bond or carbon-carbon triple bond, the blocking compound selectively depositing on the first surface over the second surface to form a blocked first surface; and
selectively depositing the low-k dielectric film on the second surface over the blocked first surface.

2. The method of claim 1, further comprising exposing the substrate to a pretreatment to remove oxide from the first surface.

3. The method of claim 1, wherein the second surface comprises silicon germanium (SiGe) having a germanium concentration in a range of from 5 atomic % to 50 atomic %.

4. The method of claim 1, wherein the blocking compound comprises an alkyne having a general formula (I): 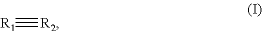
wherein R₁ and R₂ are independently selected from the group consisting of hydrogen, substituted or unsubstituted C₁₋₂₀ linear alkyl, substituted or unsubstituted C₁₋₂₀ branched alkyl, substituted or unsubstituted C₁₋₂₀ cyclic alkyl, and substituted or unsubstituted C₄₋₁₀ aryl.

5. The method of claim 4, wherein R₁ comprises hydrogen or a linear C₆₋₂₀ alkyl and R₂ is the same as R₁.

6. The method of claim 4, wherein the blocking compound comprises cyclooctyne.

7. The method of claim 1, wherein the blocking compound comprises an alkene having a general formula (II): 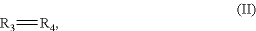
wherein R₃ and R₄ are independently selected from the group consisting of hydrogen, substituted or unsubstituted C₁₋₂₀ linear alkyl, substituted or unsubstituted C₁₋₂₀ branched alkyl, substituted or unsubstituted C₁₋₂₀ cyclic alkyl, and substituted or unsubstituted C₄₋₁₀ aryl.

8. The method of claim 7, wherein R₃ comprises hydrogen or a linear C₆₋₂₀ alkyl and R₄ is the same as R₃.

9. The method of claim 7, wherein the blocking compound comprises cyclopentadiene or cyclohexene.

10. The method of claim 1, wherein the low-k dielectric film comprises an insulating material.

11. The method of claim 10, wherein the low-k dielectric film comprises one or more of silicon oxycarbide (SiOC), silicon oxide (SiO), silicon nitride (SiN), silicon oxycarbonitride (SiOCN), aluminum oxide (AlO), aluminum silicon oxide (AlSiO), and metal oxides having a dielectric constant k with k<8.

12. The method of claim 1, wherein the low-k dielectric film has a thickness of about 10 nm or less.

13. The method of claim 1, wherein the low-k dielectric film forms an inner spacer layer of a gate-all around (GAA) transistor, and the second surface is a channel material of the gate-all-around (GAA) transistor.

14. The method of claim 1, wherein a ratio of a deposition rate of the film on the second surface to a deposition rate of the film on the first surface is about 6:1 or greater.

15. The method of claim 1, wherein the substrate is exposed to the blocking compound for a time period of greater than or equal to about 200 seconds and at a temperature in a range of from about 100° C. to about 400° C.

16. A method of forming an inner spacer layer in a gate all-around (GAA) transistor, the method comprising:
pretreating a substrate to remove oxide from a hydrogen-terminated silicon (Si) channel of the substrate, the substrate comprising the hydrogen-terminated silicon channel and a silicon germanium (SiGe) surface;
exposing the substrate to an oxidizing environment;
exposing the substrate to a blocking compound, the blocking compound comprising at least one carbon-carbon double bond or carbon-carbon triple bond, the blocking compound selectively depositing on the hydrogen-terminated silicon (Si) channel over the silicon germanium (SiGe) surface to form a blocked silicon channel; and
depositing the inner spacer layer selectively on the silicon germanium surface over the blocked silicon channel.

17. The method of claim 16, wherein the blocking compound forms a monolayer or a sub-monolayer on the hydrogen-terminated silicon channel.

18. The method of claim 16, wherein the inner spacer layer comprises one or more of silicon oxycarbide (SiOₓC_{y}), silicon oxide (SiO₂), silicon nitride (SiNₓ), silicon oxycarbonitride (SiOₓC_{y}Nₓ), aluminum oxide (AlOₓ), aluminum silicon oxide (AlSiOₓ), and metal oxides having a dielectric constant k with k<8.

19. The method of claim 16, wherein the inner spacer layer has a thickness of about 10 nm or less.

20. The method of claim 16, wherein the blocking compound comprises an alkyne having a general formula (I): 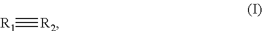
wherein R₁ and R₂ are independently selected from the group consisting of hydrogen, substituted or unsubstituted C₁₋₂₀ linear alkyl, substituted or unsubstituted C₁₋₂₀ branched alkyl, and substituted or unsubstituted C₁₋₂₀ cyclic alkyl,
or the blocking compound comprises an alkene having a general formula (II): 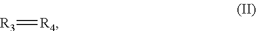
wherein R₃ and R₄ are independently selected from the group consisting of hydrogen, substituted or unsubstituted C₁₋₂₀ linear alkyl, substituted or unsubstituted C₁₋₂₀ branched alkyl, and substituted or unsubstituted C₁₋₂₀ cyclic alkyl.
